(19) United States
(12) Patent Application Publication
(10) Pub. No.: US 2025/0208504 A1
(43) Pub. Date: Jun. 26, 2025

(54) METHOD FOR MANUFACTURING PATTERNS HAVING CURVED WALLS BY PHOTOLITHOGRAPHY

(71) Applicant: ALEDIA, Champagnier (FR)

(72) Inventors: Elisabeth JACQUIN, Grenoble (FR); Christophe LINCHENEAU, Moirans (FR); Emmanuel FUCHS, Grenoble (FR); Davina MOODELLY, Noyarey (FR); Barbara PELLETIER, Saint-Egreve (FR)

(73) Assignee: ALEDIA, Champagnier (FR)

(21) Appl. No.: 18/989,845

(22) Filed: Dec. 20, 2024

(30) Foreign Application Priority Data
Dec. 21, 2023 (FR) FR2314725

(51) Int. Cl. G03F 7/004; G03F 7/00; H10H 29/01; H10H 29/80; H10H 29/851

(52) U.S. Cl. CPC G03F 7/0047; G03F 7/0007; H10H 29/0361; H10H 29/8512; H10H 29/882

(57) ABSTRACT

An embodiment relates to a method for forming by defocused lithography a stack including a photosensitive layer based on a photosensitive resin having “scattering” particles. The stack further includes at least one pattern defined at least partly by a curved lateral wall so that an intersection of the curved wall with a plane substantially perpendicular to the plane of main extension of the stack forms a curved line. An embodiment also relates to the creation of an optoelectronic device including the stack, wherein the at least one pattern is at least one cavity at least partly defined by the curved lateral wall, and at least one light-emitting diode disposed in the at least one cavity.

### TECHNICAL FIELD

The present invention relates to the field of photolithography. A particularly advantageous use thereof is the manufacturing of optoelectronic devices comprising diodes disposed in cavities, allowing the improvement of the performance of these devices.

### PRIOR ART

Photolithography is a technique routinely used to create microstructures in photosensitive layers of resin, using a mask having regions, typically made of chromium, opaque to light radiation, generally of a UV source and transparent regions, for example made of quartz, that let this radiation pass through. These regions define the desired patterns in the layer of resin, obtained after a step of insolation with the light radiation, followed by a step of development in a suitable solution.

The resulting patterns depend on several parameters such as the shape and/or the dimensions of the regions of the mask, the insolation dose, the composition of the photosensitive resin, the polarity of the resin, etc.

Methods for lithography on resins comprising titanium oxide (TiO₂) are known. TiO₂ is a large-band-gap semiconductor transparent to the wavelengths in the visible, and which absorbs ultraviolet radiation (UV). Moreover, TiO₂ has a high refractive index which makes it a suitable material for the manufacturing of optical elements such as diffraction gratings for example. The phenomenon of diffraction of the TiO₂ depends nevertheless on the size of the particle. For the manufacturing of diffraction gratings, the transfer of the patterns of the mask with a high resolution onto the layer of resin is generally carried out by focusing the beam of the radiation on the surface of the layer of photosensitive resin. Gratings with 2D patterns, and in particular with non-uniform walls, can be obtained by successive insolations. These solutions remain in practice complex to implement and not very modulable in terms of geometries that can be obtained.

One object of the present invention is therefore to propose a simplified solution allowing to obtain patterns with a curved wall by photolithography. One object of the present invention can more particularly be to propose a solution allowing to obtain cavities with a curved wall, and in particular to improve the performance of optoelectronic devices comprising a diode.

### SUMMARY

To reach this goal, according to a first aspect of the invention a method is provided for manufacturing by defocused lithography a stack comprising at least one pattern, preferably a cavity, defined at least partly by a curved lateral wall so that an intersection of the curved wall with a plane substantially perpendicular to the plane of main extension of the stack forms a curved line, the method comprising:
providing a multilayer assembly comprising a substrate surmounted by a photosensitive layer, the photosensitive layer having an exposed surface and being based on a photosensitive resin comprising “scattering” particles, capable of scattering an incident light radiation,
providing a mask comprising at least one region configured to transmit the incident light radiation,
placing the mask and the multilayer assembly so as to space them apart by a distance D1 configured so that the exposed surface of the photosensitive layer is not disposed in a plane of focus of the incident light radiation,
the mask and the multilayer assembly being separated by the distance D1, an insolation of at least a part of the photosensitive layer, by the incident light radiation transmitted through the at least one region, wherein the incident light radiation is scattered laterally by the particles as the incident light radiation penetrates into the photosensitive layer, so as to form at least one insolated region defined at least partly by a curved lateral wall, and at least one non-insolated region,
forming the at least one pattern, preferably a cavity in the multilayer assembly, the formation comprising a removal of one out of the insolated region and the non-insolated region, to obtain the stack.

These various steps of the method allow to manufacture on a substrate patterns with a curved lateral wall from a photosensitive layer of resin, by “defocused” photolithography.

In the present invention, the integration of scattering particles into the composition of the photosensitive resin allows the progressive lateral scattering of the defocused radiation penetrating the layer of resin. The synergy between the defocusing of the incident light radiation and its scattering by the scattering particles allows a progressive irradiation in the photosensitive layer. This progressive irradiation occurs at least according to a direction included in the plane of main extension of the photosensitive layer, in a homogeneous and continuous manner, which allows to define a curved lateral wall defining the insolated region. The removal of the insolated region or of the non-insolated region, according to whether a respectively positive or negative resin is used, after a step of development in a solution, respectively leads to a stud or a cavity having curved lateral walls. According to the parameters of the method, and for example the parameters of defocusing, of load of scattering particles, the shape of the curved wall can furthermore be modulated in a simplified manner. In particular, the depth of the pattern can be modulated according to the needs.

This approach thus differs completely from the conventional photolithography methods. Indeed, in these conventional methods, the mask and the photosensitive layer of resin are positioned with respect to one another so as to focus the insolation radiation on the exposed surface of the photosensitive layer. Patterns with straight sharp walls are generally aimed at, in order to obtain an accurate reproduction of the pattern of the mask on the photosensitive layer.

A second aspect of the invention relates to a stack comprising:
a substrate surmounted by a photosensitive layer based on a photosensitive resin comprising particles capable of scattering an incident light radiation having a first mass percentage,
the photosensitive layer comprising at least one pattern at least partly defined by a curved lateral wall so that an intersection of the curved wall with a plane substantially perpendicular to the plane of main extension of the stack forms a curved line, the photosensitive layer having an exposed surface, and the at least one pattern opening onto the exposed surface.

This stack comprising patterns having curved lateral walls can be integrated into various microelectronic devices according to the intended use, and in particular into optoelectronic devices or display devices comprising light-emitting diodes or photodiodes for example.

A third aspect of the invention relates to an optoelectronic device comprising the stack described above, and at least one light-emitting diode, wherein the pattern surmounts preferably the light-emitting diode. According to one example, the at least one pattern is at least one cavity defined at least partly by the curved lateral wall, and the at least one light-emitting diode disposed in the at least one cavity, the cavity being configured so as to at least partly expose the light-emitting diode.

The use of patterns having curved walls manufactured by the method according to the first aspect, and in particular cavities, allows to improve the performance of this device. The curved and reflective walls of the patterns allow in particular to improve the extraction of the light radiation emitted by the diodes arranged inside the cavities.

### BRIEF DESCRIPTION OF THE DRAWINGS

The goals, objects, features and advantages of the invention will be better understood from the detailed description of an embodiment of the latter that is illustrated by the following accompanying drawings in which:

FIGS. 1A, 1B, 2, 3, 5A to 5D schematically illustrate according to transverse cross-sections xz steps of manufacturing a stack comprising patterns having curved walls according to a first embodiment of the present invention.

FIGS. 4A and 4B schematically illustrate according to transverse cross-sections xz the variation in the curvature of the patterns manufactured according to the present invention according to various parameters.

FIGS. 6A and 6B schematically illustrate according to transverse cross-sections xz steps of manufacturing a stack comprising patterns having curved walls according to a second embodiment of the present invention.

FIG. 6C schematically illustrates according to a perspective view the manufacturing of a stack comprising patterns having curved walls according to a third embodiment of the present invention.

FIGS. 7, 8, 9A, 9B, 10, 11 and 12 schematically illustrate according to transverse cross-sections xz steps of manufacturing an optoelectronic device comprising cavities having curved walls and light-emitting diodes according to an embodiment of the present invention.

FIG. 13 shows images of the cavities having curved walls manufactured according to the present invention, taken by scanning electron microscopy.

The drawings are given as examples and do not limit the invention. They constitute schematic outline representations intended to facilitate understanding of the invention and are not necessarily plotted to the scale of practical applications. In particular, the thicknesses and/or the dimensions of the various layers, patterns and reliefs are not representative of the reality.

### DETAILED DESCRIPTION

Before undertaking a detailed review of embodiments of the invention, optional features are listed below that can optionally be used in combination or alternatively:

According to one example, the distance D1 is strictly greater than a distance between the mask and the focus plane.

According to one example, the incident light beam on the photosensitive layer is divergent, at least between the mask and the exposed surface. The incident beam can be straight or divergent between the source of the light beam and the mask.

According to one example, the distance between the mask and the focus plane is chosen so that the exposed surface is distant from the focus plane by a distance D2 of between 100 nm and 100 μm, preferably between 10 μm and 100 μm.

The distance D2 allows to control the slope of the lateral walls of the patterns. When the incident light radiation is focused on the exposed surface of the photosensitive layer and in the absence of scattering particles, the walls of the patterns obtained are sharp and straight. The farther the photosensitive layer from the focus plane, the more the incident light radiation diverges, while remaining straight, while penetrating the photosensitive layer, and the more the slope of the curved lateral wall of the pattern obtained tends to be weak. As for the presence of scattering particles in the photosensitive layer, it allows the curvature of the walls.

According to one example, the incident light radiation is scattered laterally as the radiation penetrates the photosensitive layer so as to form a scattering gradient, the cross-section of which, in a plane perpendicular to a main direction of propagation of the incident light radiation, increases as the incident light radiation penetrates into the photosensitive layer.

According to one example, the at least one pattern has in the plane of main extension of the stack an only increasing or only decreasing transverse cross-section, preferably strictly, along a direction perpendicular to the plane of main extension of the stack when moving away from the substrate.

According to one example, and as is directly clear from the description, the at least one pattern has in the plane of main extension of the stack a transverse cross-section having an increasing, and more particularly strictly increasing, surface area along a direction perpendicular to the plane of main extension of the stack when moving away from the substrate. In an equivalent manner, the at least one pattern has in the plane of main extension of the stack a transverse cross-section having a decreasing, and more particularly strictly decreasing, surface area along a direction perpendicular to the plane of main extension of the stack in the direction of the substrate. The pattern formed thus has a flared shape when moving away from the substrate. This differs from a cavity having a cross-section with a diameter restriction, or in an equivalent manner having an increasing then decreasing cross-section along a direction perpendicular to the plane of main extension of the stack in the direction of the substrate, which limits the extraction of the light.

Said transverse cross-section can be circular. It is thus understood that the diameter of the pattern can be decreasing along a direction perpendicular to the plane of main extension of the stack and in the direction of the substrate.

According to one example, the photosensitive layer is based on a negative resin and the at least one pattern obtained is at least one cavity.

According to another example, the photosensitive layer is based on a positive resin and the at least one pattern obtained is at least one stud.

According to one example, the scattering particles are chosen from the group consisting of: oxides of metals having the formula MₓO_{y}, with x, y non-zero positive integers, such as titanium dioxide (TiO₂), zinc oxide (ZnO), manganese oxide (MnO), the oxides of the lanthanides (Ln₂O₃), aluminum oxide (Al₂O₃), magnesium oxide (MgO), silicon oxide (SiO₂), the iron oxides (FeₓO_{y}), zirconium oxide (ZrO₂), and nanoparticles based on at least one metal such as silver (Ag), gold (Au), platinum (Pt), nickel (Ni), aluminum (Al) or chromium (Cr).

These scattering particles allow on the one hand the scattering of the incident light radiation in the photosensitive layer during the insolation step. On the other hand, via the good reflectivity of the metal materials, the scattering particles based on these materials allow the reflection of a light radiation incident to the wall of the resulting pattern.

The scattering of the incident light radiation in the photosensitive layer varies according to the nature of the scattering particles as well as their dimension. The dimension of these scattering particles is generally approximately the same as the wavelength of the incident light radiation.

According to one example, the scattering particles are capable of scattering an incident light radiation having a wavelength in the ultraviolet equal to 365 nm, 248 nm or 193 nm.

According to one example, the photosensitive layer is based on a negative photosensitive resin, so that, during the formation of the at least one pattern, the removal of the non-insolated region induces the formation of at least one cavity defined at least partly by the curved lateral wall.

The exposure of a negative resin to an insolation light radiation allows the cross-linking of the insolated region of the photosensitive layer of resin. The progressive lateral scattering of the insolation radiation by the scattering particles present in the photosensitive layer allows to define a non-insolated region defined by the curved lateral walls. An intersection of these walls with a plane substantially perpendicular to the plane of main extension of the photosensitive layer forms curves lines. The radii of curvature of these curved lines extend in the non-insolated region.

During the development step, when starting from a negative resin, the non-insolated region is dissolved thus forming a cavity. The curvature of the walls of this cavity has a radius of curvature that extends at least partly in the cavity.

In the case of a positive resin, the insolated region is dissolved during the development thus forming a stud. The stud formed has a curved lateral wall, the radius of curvature of which extends at least partly in the stud. The stability of the stud can be improved by playing with the parameters that control the curvature or the slope of the curved walls.

According to one example, and in particular when the resin is a positive resin, the formation of the at least one cavity comprises a removal of the insolated region by dissolution during the development and the molding of an additional layer on the photosensitive layer, so as to form the at least one cavity in the additional layer. It is thus understood that the stud formed in the photosensitive layer is used as an imprint for the formation of the at least one cavity. In other words, the at least one cavity can be obtained in fine by transferring the shape of the stud formed after the development of the positive photosensitive resin into an additional layer.

According to one example, the photosensitive resin has a mass proportion of scattering particles between 1% and 40%, preferably between 3% and 20%.

According to one example, the mass proportion of the scattering particles is taken with respect to the total mass in the solid state of the photosensitive layer.

The mass percentage of the scattering particles present in the photosensitive layer is a particularly advantageous parameter for controlling the slope or the curvature of the walls of the patterns. The more the resin is loaded with scattering particles, the more the incident light radiation is scattered laterally in the photosensitive layer, which results in a small slope of the wall. Moreover, the mass percentage of the scattering particles acts on the reflectivity of the walls of the patterns. The more the resin is loaded with scattering particles, the greater the reflectivity of the walls.

According to one example, the scattering particles have a reflectivity between 20% and 100%, preferably between 75% and 100%.

According to one example, the reflectivity of the scattering particles can be controlled by varying the dimension of the scattering particles, their mass proportion and the wavelength of the incident light radiation.

In the case of an optoelectronic device, the positioning of a light-emitting diode inside a cavity having reflective walls allows the reduction of the losses of the radiation emitted by the diodes. The reflectivity of these walls is thus advantageously optimized to be maximal.

According to one example, the thickness of the photosensitive layer is between 5 μm and 100 μm.

According to one example, the thickness of the photosensitive layer can be advantageously adapted for a use of an optoelectronic device comprising light-emitting diodes.

According to one example, the photosensitive layer comprises several sublayers at least partly superimposed.

According to one example, the sublayers of the photosensitive layer are based on a negative photosensitive resin.

According to one example, at least two sublayers have a mass proportion of scattering particles distinct from one another, and preferably each sublayer has a mass proportion of scattering particles distinct among the several sublayers.

According to one example, the mass proportion of scattering particles increases between two superimposed, and preferably successively superimposed, sublayers when moving away from the exposed surface.

According to one example, the sublayers of the photosensitive layer are based on a positive photosensitive resin.

According to one example, the mass proportion of scattering particles decreases between two superimposed, and preferably successively superimposed, sublayers when moving away from the exposed surface.

The slope of the curved lateral walls of the patterns can also be modulated by starting from a multilayer assembly of several sublayers of resins and by varying the mass percentage of the scattering particles from one sublayer to another, according to whether they are based on a negative or positive resin.

According to one example, the at least one insolated region is subjected to an insolation dose of between 50 mJ/cm² and 3000 mJ/cm².

The insolation dose allows to control the depth and the dimensions of the patterns.

According to one example, the photosensitive layer is based on a negative photosensitive resin, there is at least one light-emitting diode above the substrate of the stack disposed at the interface between the substrate and the photosensitive layer, and the insolation is configured so that the cavity at least partly exposes the at least one light-emitting diode.

The cavities having reflective curved walls allow the improvement of the extraction of the radiation emitted by the light-emitting diodes.

According to one example, the method comprises, after the formation of the at least one cavity, the deposition of a solution comprising a color conversion module in the at least one cavity exposing the at least one light-emitting diode.

The introduction of color conversion modules into the cavities allows a conversion of the wavelength of the light radiation emitted by the light-emitting diode. The wavelength of the light reemitted by the color conversion modules depends on the size and the composition of these color conversion modules.

According to one example, the light-emitting diode being configured to emit a light radiation having a first wavelength, the color conversion modules are configured to convert the first wavelength into a second wavelength distinct from the first wavelength.

According to one example, the conversion modules can comprise luminophores, or photoluminescent particles. According to one example, the photoluminescent particles are dispersed in a transparent matrix, for example based on a photosensitive resin. According to one example, the photoluminescent particles are quantum dots.

According to one example, the solution comprising the color conversion modules further comprises scattering particles, capable of diffusing a radiation emitted by the at least one light-emitting diode.

According to one example, the solution comprising color conversion modules has a mass proportion of scattering particles smaller than a mass proportion of the scattering particles in the photosensitive layer.

According to one example, the solution comprising color conversion modules has a mass proportion of scattering particles distinct and preferably smaller than a mass proportion of the scattering particles in the photosensitive layer, preferably strictly smaller than a mass proportion of the scattering particles in the photosensitive layer.

The introduction of scattering particles into the solution comprising color conversion modules allows the scattering of the light radiation emitted by the light-emitting diode and of the light radiation reemitted by the color conversion modules, which improves the conversion of the wavelength and the extraction of the light radiation from the cavities.

According to one example, the at least one pattern of the stack has a depth of between 5 μm and 30 μm.

In the case in which the pattern corresponds to a cavity, the depth of the cavity determines the quantity of color conversion modules that can be introduced into the cavity. This allows the optimization of the conversion of the wavelength by the color conversion modules and of the extraction of the radiation reemitted by the color conversion modules or of the radiation emitted by the light-emitting diodes.

The depth of the cavity depends on the insolation dose and the distance between the mask and the exposed surface of the photosensitive layer.

According to one example, the at least one pattern of the stack is at least one cavity at least partly defined by the curved lateral wall.

According to one example, the at least one pattern of the optoelectronic device comprising the stack is preferably at least one cavity at least partly defined by the curved lateral wall, and at least one light-emitting diode disposed in the at least one cavity, the cavity being configured so as to at least partly expose the light-emitting diode.

According to one example, the optoelectronic device comprises a solution in the at least one cavity, the solution comprising color conversion modules.

According to one example, the optoelectronic device comprises a solution in the at least one cavity, the solution comprising color conversion modules with scattering particles, the solution comprising color conversion modules having a mass proportion of scattering particles smaller than a mass proportion of the scattering particles in the photosensitive layer.

The integration into the optoelectronic device of the cavities comprising a solution comprising color conversion modules with scattering particles allows:
The improvement of the efficiency of extraction of the light radiation emitted by the luminescent photodiodes or reemitted by the color conversion modules, by adjusting the depth and the slope of the curved lateral walls of the cavity.
The improvement of the efficiency of the conversion of the wavelength by the color conversion modules by adjusting the depth and the slope of the curved lateral walls of the cavity.
The limitation of the optical crosstalk between two cavities, the optical crosstalk being the contamination of a wavelength reemitted by the color conversion modules inside a cavity by the wavelength emitted by the light-emitting diode inside the neighboring cavity. This crosstalk is possible for any wavelength. For example, an emission of a first blue radiation in a cavity can contaminate an emission of a second red or green radiation in a neighboring cavity. According to another example, an emission of a first green radiation in a cavity can also contaminate an emission of a second red or blue radiation in a neighboring cavity. According to another example, an emission of a first red radiation in a cavity can also contaminate an emission of a second green or blue radiation in a neighboring cavity. The contamination by a blue radiation can in particular be caused by a leak of the blue radiation. The contamination by a green or red radiation can be the result of a leak of the green or red radiation, or of a chemical contamination inside the cavity.
The improvement of the far-field emission of the radiation of the light-emitting diodes.
The improvement of the contrast between the emission of two neighboring light-emitting diodes.

According to one example, the optoelectronic device comprises at least three light-emitting diodes configured to emit a light radiation having a first wavelength, for example in the blue, and disposed so that:
a first light-emitting diode is disposed in a first cavity comprising a first solution, the first solution comprising first color conversion modules and scattering particles, the first color conversion modules being configured to convert the first wavelength of the light radiation emitted by the first light-emitting diode into a second wavelength different from the first wavelength, preferably the second wavelength is in the red,
a second light-emitting diode is disposed in a second cavity comprising a second solution, the second solution comprising second color conversion modules and scattering particles, the second color conversion modules being configured to convert the first wavelength of the light radiation emitted by the second light-emitting diode into a third wavelength different from the first and second wavelengths, preferably the third wavelength is in the green,
a third light-emitting diode is disposed in a third cavity and emitting at the first wavelength, the third cavity comprising a third solution, the third solution comprising scattering particles.

According to one example, the first wavelengths emitted by the light-emitting diodes are substantially equal to each other. It is possible for these wavelengths emitted by the light-emitting diodes to be distinct from each other.

According to one example, the third solution is free of color conversion modules comprising scattering particles.

According to one example, the stack of the optoelectronic device further comprises a first layer opaque to the wavelengths of the visible, covering at least partly, and preferably entirely, the exposed surface of the photosensitive layer.

According to one example, the first opaque layer can be configured so as to separate the cavities from each other.

According to one example, the optoelectronic device further comprises a second layer opaque to the first wavelength, for example in the blue of the light radiation emitted by the light-emitting diodes, disposed above the first and second cavities, so as to let the second and third wavelengths converted by the color conversion modules pass through and block the first wavelength in the blue of the light radiation emitted by the light-emitting diodes.

“Optoelectronic device” is taken to mean a device suited to emitting, conveying, or receiving light. According to a specific use, such an optoelectronic device comprises light-emitting diodes (LEDs), in particular LEDs forming subpixels of a pixel of an emitting screen.

The invention may be implemented more broadly for different optoelectronic devices. The invention may for example be implemented in the context of laser or photovoltaic devices. LEDs or optoelectronic devices typically have in the context of the present invention dimensions, in projection in a base plane xy, smaller than 100 μm*100 μm, preferably smaller than 10 μm*10 μm. Unless explicitly stated, it is specified that, within the scope of the present invention, the relative disposition of a second layer intercalated between a first layer and a third layer does not necessarily mean that the layers are directly in contact with each other, but means that the second layer is either directly in contact with the first and third layers, or separated therefrom by at least one other layer or at least one other element.

Thus, the terms and phrases “bear on”, “surmount”, “cover” or “overlap” do not necessarily mean “in contact with”.

The steps of the method are understood in the broad sense of the carrying out of a part of the method and can optionally be carried out in several substeps. Several embodiments of the invention implementing successive steps of the manufacturing method are described below. Unless explicitly stated, the adjective “successive” does not necessarily mean, even if this is generally preferred, that the steps succeed each other immediately, and intermediate steps can separate them.

Moreover, the term “step” does not necessarily mean that the actions carried out during a step are simultaneous or immediately successive. Certain actions of a first step can in particular be followed by actions related to a different step, and other actions of the first step can be continued afterwards. Thus, the term step does not necessarily mean unitary and inseparable actions in time and in the succession of the phases of the method.

In the present patent application, the terms “light-emitting diode”, “LED” or simply “diode” are used as synonyms. A “LED” may also mean a “micro-LED” or a “smart LED”.

A substrate, a layer, a device, “based on” a material M is taken to mean a substrate, a layer, a device comprising only this material M or this material M and possibly other materials, for example alloying elements, impurities or doping elements. Thus a GaN-based diode typically comprises GaN and AlGaN or InGaN alloys.

In the context of the present invention, an organic or organo-mineral material that can be shaped by an exposure to a beam of electrons, of photons or of X-rays or mechanically is conventionally qualified as a resin.

Examples of resins conventionally used in microelectronics include resins based on polystyrene (PS), methacrylate (for example PMMA polymethyl methacrylate), hydrogen silsesquioxane (HSQ), polyhydroxystyrene (PHS), etc. The interest of using a resin is that it is easy to deposit a significant thickness thereof, from several hundred nanometers to several microns.

Antireflection layers and/or coatings can be associated with the resins. This allows in particular to improve the lithography resolution. Hereinafter, the various masks based on resin are preferably associated with such antireflection layers.

Within the scope of the present invention, a “transparent” object or material means that the object or the material allows at least 90% of the light intensity of the light beam that passes through it to pass. Conversely, a material or a surface is considered as “opaque” from the moment that it absorbs or stops at least 85% of the intensity of an incident light beam.

The dimensional values should be understood considering the manufacturing and measurement tolerances.

The terms “substantially”, “about”, “of the order of” mean, when they relate to a value, “to within 10%” of this value or, when they relate to an angular orientation, “to within 10°” of this orientation. Thus a direction substantially normal to a plane means a direction having an angle of 90±10° with respect to the plane.

It is specified that in the context of the present invention, the thickness of a layer or of the substrate is measured according to a direction perpendicular to the surface according to which this layer or this substrate has its maximum extension. The thickness is thus taken according to a direction perpendicular to the main faces of the layer or of the substrate on which the various layers rest. More particularly, the thickness can be taken according to the direction z.

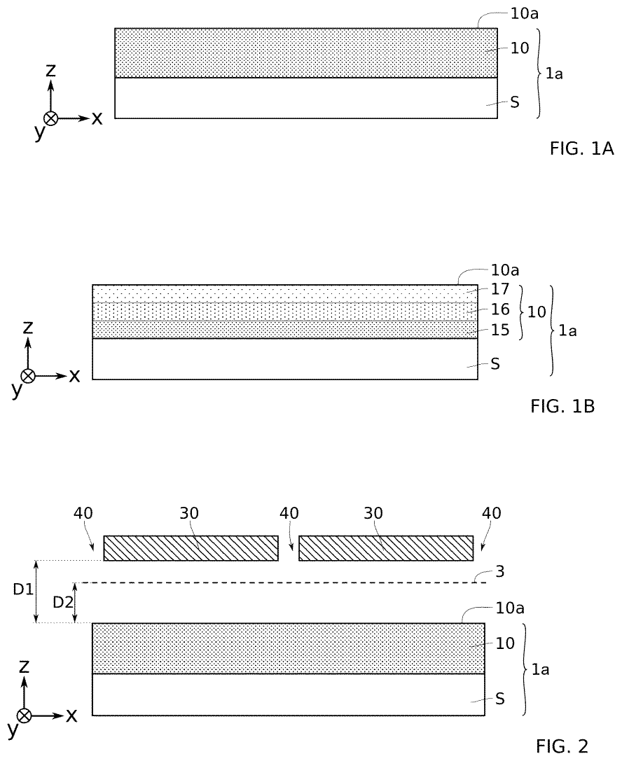

The method for manufacturing a stack 1 comprising at least one pattern 20, 20′ having a curved wall by defocused lithography is now described in reference to FIGS. 1A, 1B, 2, 3, 4A, 4B, 5A to 5D, 6A and 6B, according to specific exemplary embodiments. Hereinafter, it is considered in a non-limiting way that several patterns, cavities or studs are formed.

As illustrated in FIG. 1A, the method comprises providing a multilayer assembly 1a comprising a substrate S surmounted a photosensitive layer 10 having an exposed surface 10a. The multilayer assembly 1a extends according to a plane xy defined by a direction x and a direction y perpendicular to the direction x.

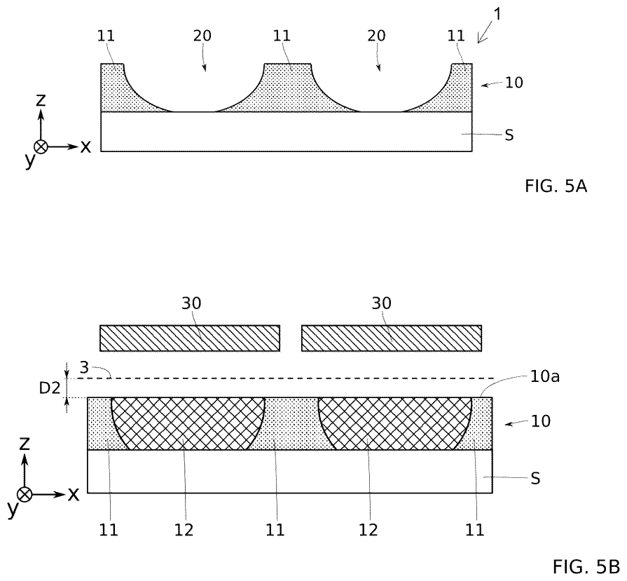

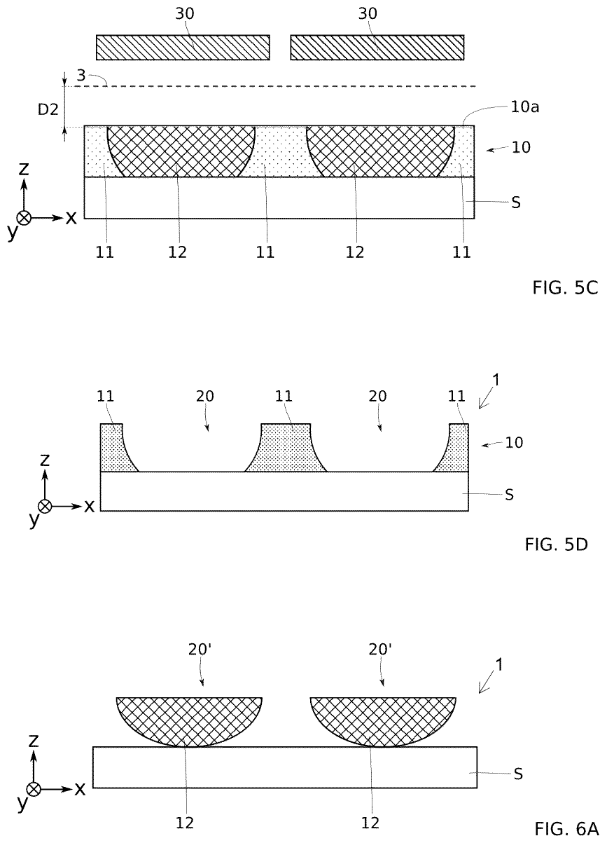

The photosensitive layer 10 is based on a photosensitive resin, the chemical properties of which are modified upon exposure to a light radiation 2 (not illustrated in this drawing) incident to the exposed surface 10a. The photosensitive layer 10 comprises particles capable of scattering the incident light radiation 2. Thus, the incident light radiation 2 is scattered at least laterally, according to at least one direction included in the plane xy. Moreover, these particles have a high reflectivity, which allows to obtain patterns 20, 20′ (illustrated starting from FIG. 5A) having reflective walls.

The method further comprises providing a mask 30 comprising regions opaque to the incident light radiation 2, and regions 40 configured to let the incident light radiation 2 pass through. According to one example, the opaque regions can be for example in the shape of opaque studs, for example distinct from each other, surrounded by one or more transparent regions 40, for example as illustrated by FIGS. 2 to 5C. According to an alternative example, described in more detail below, the mask 30 can comprise at least one opaque region in which transparent regions 40, and more particularly openings, let the light radiation pass through. The shape of the transparent regions 40 of the mask 30 is generally transposed to the resin-based photosensitive layer 10. Other parameters come into play in the definition of the geometric shape and the dimensions of the resulting patterns. These parameters will be described in the course of the following description.

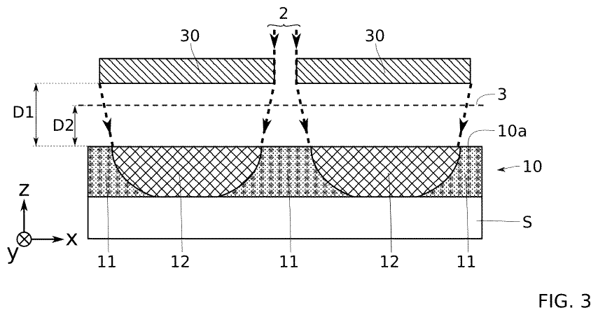

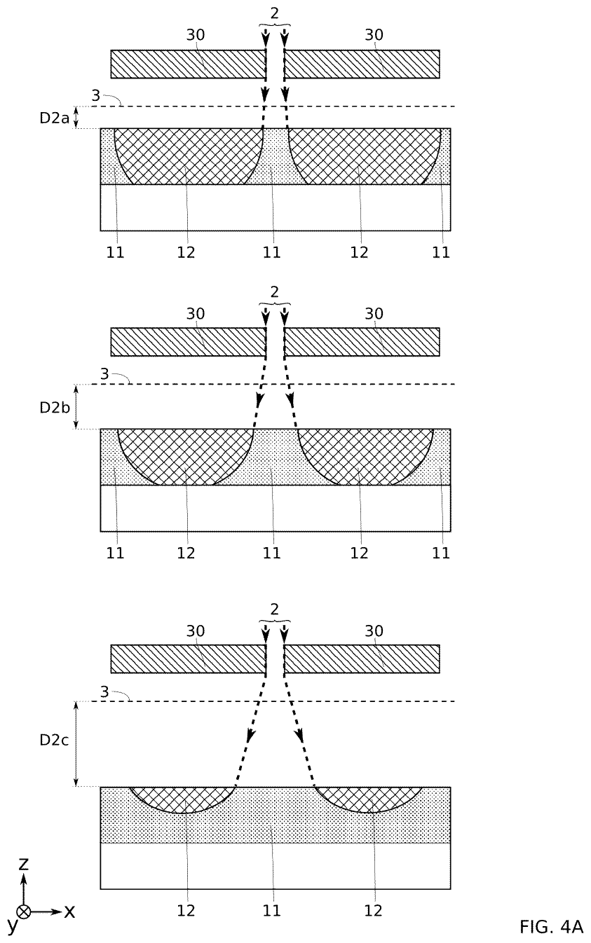

As illustrated in FIG. 2, the mask 30 and the multilayer assembly 1a are placed so as to space them apart by a distance D1. This distance D1 is configured so that the exposed surface 10a of the photosensitive layer 10 is not disposed in a focus plane 3 of the incident light radiation 2. In other words, the distance D1 is configured in order to obtain a beam of the light radiation 2 that diverges beyond the focus plane 3, as illustrated in FIG. 3, after its transmission through the regions 40. This location allows to obtain a defocused image of the exposed surface 10a, hence the term “defocused lithography”.

The mask 30 and the multilayer assembly 1a being separated by the distance D1, the method then comprises an insolation of the parts of the photosensitive layer exposed to the transparent regions 40 by the incident light radiation 2. Upon its incidence at the exposed surface 10a, the incident light radiation 2 is scattered by “scattering” particles present in the photosensitive layer 10. This scattering occurs in all directions in a homogeneous and continuous manner, so as to form a scattering gradient, the cross-section of which in a plane substantially perpendicular to the direction z of propagation of the light beam, for example in a plane parallel to the plane xy, increases as it penetrates into the photosensitive layer 10, along the direction z substantially perpendicular to the directions x and y.

The divergence of the incident light radiation 2, in synergy with the lateral scattering of the incident light radiation 2 by the scattering particles, allows the formation of a plurality of insolated regions 11 at least partly defined by a curved lateral wall, and a plurality of non-insolated region 12 separated by the insolated regions 11. An intersection of this curved lateral wall with a plane substantially perpendicular to the plane xy forms curved lines.

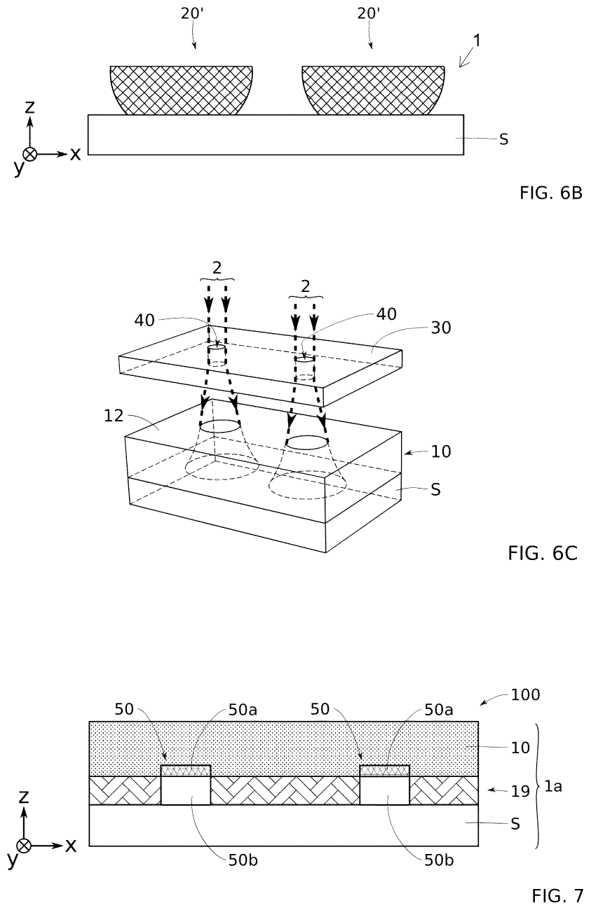

As illustrated in FIGS. 5A and 6A, the method then comprises the formation of patterns 20, 20′ having curved walls by removal of the insolated regions 11, or of the non-insolated regions 12, respectively during a step of development, as explained below.

According to a first alternative, in the case of a photosensitive layer 10 based on a negative resin, the insolation by the incident light radiation 2 allows the cross-linking of the resin in the insolated regions 11. Since the non-insolated regions 12 are soluble, they are then removed by a specific solvent, thus forming hollow cavities 20 having curved lateral walls as shown in FIG. 5A.

According to a second alternative, in the case of a photosensitive layer 10 based on a positive resin insoluble in its initial state, the insolation by the incident light radiation 2 through the same mask illustrated in the preceding figures allows to make the insolated regions soluble in a specific solvent. The insolated regions 11 are then removed, forming studs 20′ having curved walls as shown in FIG. 6A. It should be noted that it is possible to then form one or more cavities by a step of molding an additional layer from the photosensitive layer 10. For example, a layer can be deposited on the stack 1 having the studs 20′ by molding. The layer thus molded will thus have cavities complementary to the patterns formed by the studs 20′. This layer can then for example be added onto a substrate S to form a stack 1 comprising cavities.

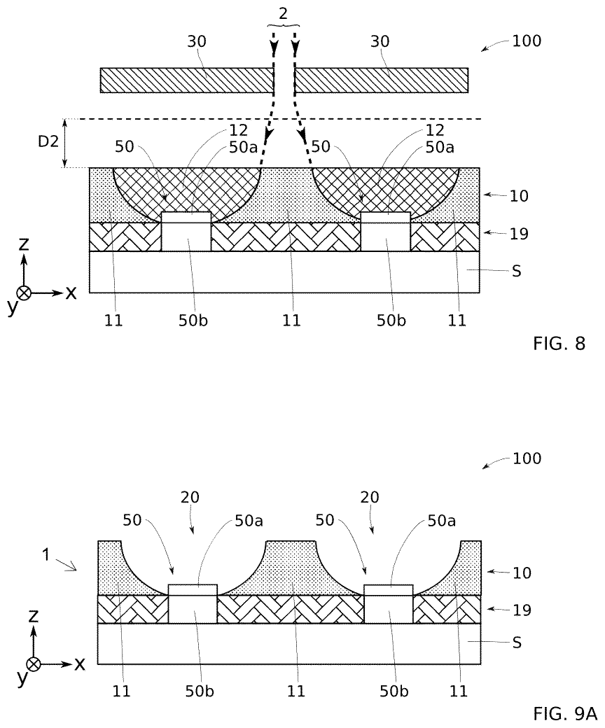

The substrate S of the stack 1 obtained depends on the use of the method of the present invention. The substrate can for example be based on glass, polyamide. The substrate can also be an FR4 printed circuit board (FR4 PCB, or “Flame Retardant”). In the case of an optoelectronic device 100 for example illustrated in FIG. 8, the substrate S can be based on functional materials such as sapphire, “TFT” (“Thin-Film transistor”), a complementary metal-oxide-semiconductor (CMOS technology), or silicon. The substrate S can also correspond to a display support structure, known as “backplane”. This structure can comprise conductive tracks, connectors, and other elements known for connecting light-emitting diodes for example.

The photosensitive layer 10 is based on a resin photosensitive to the incident light radiation 2. This photosensitive resin is configured to absorb a wavelength of the incident light radiation, preferably a wavelength in the ultraviolet (UV). It can be transparent to visible or white light. The photosensitive layer 10 is manufactured on the substrate S, in general, by spin-coating deposition. The thickness of the photosensitive layer is adapted according to the desired depth of the resulting patterns and use of the method. It is typically between 5 μm and 100 μm, preferably equal to 20 μm for an optoelectronic device 100.

After its deposition, the photosensitive layer 10 can advantageously undergo a first “soft” annealing heat treatment (“soft-bake”), which allows to improve its stability. This first annealing heat treatment is implemented, preferably, at 110° C., for example for a duration of 2 min.

The scattering particles present in the photosensitive layer 10 are configured to scatter the incident light radiation 2. The improvement of the scattering of the incident light radiation allows in particular the lateral extension of the insolated region in the plane xy. The scattering of these particles depends in particular on their nature, the size of the particles, as well as their load in the photosensitive layer, or their mass proportion relative to the total mass of the photosensitive layer 10.

In order to improve the scattering of the incident light radiation 2, the size of the particles can be adapted. Preferably, the size of these particles, for example the average diameter, is chosen approximately equal to the wavelength of the incident light radiation 2. The wavelength of the incident light radiation 2 can be chosen in the visible or in the near infrared. The choice of the wavelength can potentially affect the resolution of the lithography. The wavelength of the incident light radiation 2 is typically chosen in the spectral range of the UV which corresponds to the existing and standard equipment in microelectronics. It can be equal to 365 nm (“I-line”), 248 nm or 193 nm (deep ultraviolet, “DUV”). On the basis of this spectral range, the average diameter of the scattering particles can be chosen between 100 nm and 1000 nm, preferably between 100 nm and 500 nm, preferably between 150 nm and 300 nm.

The scattering particles present in the photosensitive layer 10 are further configured to improve the reflectivity of the surfaces of the resulting patterns. The reflectivity of the scattering particles depends on the type of material chosen, the size of the particles as well as their mass proportion relative to the total mass of the photosensitive layer 10. For example, the choice of a material comprising at least one metal allows to improve the reflectivity of the scattering particles. According to the material chosen and the load of the particles in the photosensitive layer 10, the scattering particles have a reflectivity between 20% and 100%, preferably between 75% and 100%.

The scattering particles are chosen from the group consisting of: oxides of metals having the formula MₓO_{y}, with x, y non-zero positive integers, such as titanium dioxide (TiO₂), zinc oxide (ZnO), manganese oxide (MnO), the oxides of the lanthanides (Ln₂O₃), aluminum oxide (Al₂O₃), magnesium oxide (MgO), silicon oxide (SiO₂), the iron oxides (FeₓO_{y}), zirconium oxide (ZrO₂), and nanoparticles based on at least one metal such as silver (Ag), gold (Au), platinum (Pt), nickel (Ni), aluminum (Al) or chromium (Cr).

The mass proportion of the scattering particles in the photosensitive layer 10 represents the ratio of the total mass of the scattering particles to the total mass of the photosensitive layer 10 in the solid state. This mass proportion is a particularly advantageous parameter for controlling the slope or the curvature of the walls of the patterns. The more the photosensitive resin is loaded with scattering particles, the more the incident light radiation 2 is scattered laterally according to the plane xy in the photosensitive layer, which results in a small slope of the wall. Moreover, the increase in the mass proportion of the scattering particles in the photosensitive layer 10 allows the improvement of the reflectivity of the walls of the resulting patterns. The photosensitive resin has a mass proportion of scattering particles between 1% and 40%, preferably between 3% and 20%.

According to an alternative of the present invention, the photosensitive layer 10 can comprise several sublayers 15, 16, 17, superimposed according to the direction z, as illustrated in FIG. 1B.

Each sublayer 15, 16, 17 has a mass proportion of scattering particles distinct among several sublayers 15, 16, 17. This mass proportion can vary from one sublayer to another. The variation in the mass proportion represents an additional parameter that allows to modulate the curvature or the slope of the curved walls of the resulting patterns.

According to an alternative of the present invention, the sublayers 15, 16, 17 are based on a negative resin, and the mass proportion of the scattering particles increases between two successive sublayers when moving away from the exposed surface 10a.

According to another alternative of the present invention, the sublayers 15, 16, 17 are based on a positive resin, and the mass proportion of the scattering particles can decrease or increase between two successive sublayers when moving away from the exposed surface 10a, according to the desired curvature of walls. The variation, from one sublayer to another, of the mass proportion of the scattering particles, based on TiO₂ for example, can be less than or equal to 30% for example. This variation can be approximately 3%, 6%, 9% and 12% for example. Significant changes in scattering values were measured for these values. Other values of variation of the mass proportion from one sublayer to another are however possible.

The geometry of the insolated regions 11 and of the non-insolated regions 12 that will define the geometry of the patterns 20, 20′ after development according to the type (negative or positive) of the photosensitive resin can be controlled by several parameters such as the dose of insolation by the incident light radiation 2, the location of the mask with respect to the exposed surface 10a and the mass proportion of the scattering particles in the photosensitive layer 10.

The insolation dose determines the quantity of energy absorbed by the photosensitive resin during the exposure to the incident light radiation 2. This insolation dose allows to control the depth of the insolated region 11, and consequently, the depth of the pattern 20, 20′ obtained after development. Moreover, the insolation dose allows to control the outer dimensions of the insolated region 11, in other words, the lateral dimensions of the insolated region 11 in the plane of the exposed surface 10a, typically parallel to the plane xy. By controlling the outer dimensions of the insolated region 11, the distance that separates two juxtaposed patterns 20, 20′ is also controlled. By increasing the insolation dose, the depth of the pattern 20, 20′ increases and the distance separating two neighboring patterns 20, 20′ decreases. The insolation dose is typically between 50 mJ/cm² and 3000 mJ/cm².

According to one example, the mask 30 is disposed in a manner parallel to the exposed surface 10a. The mask 30 is in particular placed with respect to the exposed surface 10a so that the distance D1 is strictly greater than a distance between the mask 30 and the focus plane 3. This distance between the mask 30 and the focus plane 3 is chosen so that the exposed surface 10a is distant from the focus plane 3 by a distance D2. The variation in the distance D2 allows to control the slope of the curved lateral wall defining the insolated region 11 and the non-insolated region 12. When the incident light radiation 2 is focused on the exposed surface 10a of the photosensitive layer 10, that is to say when the distance D2 is zero, and in the absence of scattering particles in the photosensitive layer, the lateral walls of the insolated region 11 or of the non-insolated region 12 are sharp and straight. The farther the position of the exposed surface 10a of the photosensitive layer 10 moves from the focus plane 3, that is to say the more the distance D2 increases, the more the incident light radiation 2 diverges while penetrating the photosensitive layer 10, and consequently, the slope of the lateral walls of the insolated region 11 or of the non-insolated region 12 decreases. The distance D2 can be between 100 nm and 100 μm, preferably between 10 μm and 100 μm.

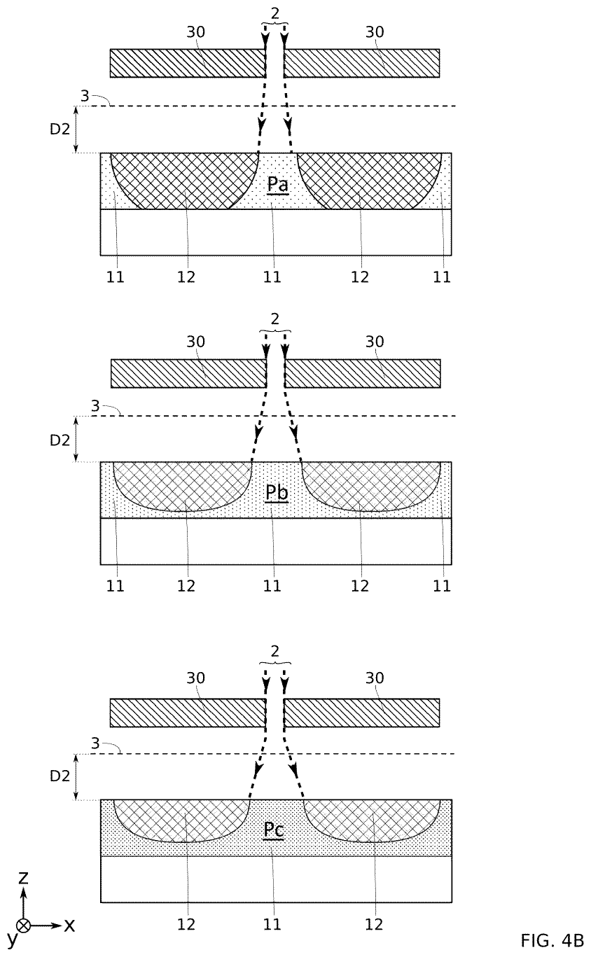

FIG. 4A illustrates various locations of the mask with respect to the exposed surface 10a, for three different distances D2a<D2b<D2c, and for a fixed mass proportion of scattering particles, here in the case of a negative resin. For a small distance D2a, the lateral walls of the non-insolated region 12 have a significant slope, and the depth of the non-insolated region 12 extends to the lower face of the photosensitive layer 10, thus forming a straight transverse wall separating the curved lateral walls. For an intermediate distance D2b, the lateral walls of the non-insolated region 12 have a smaller intermediate slope and move towards one another, and the depth of the non-insolated region 12 extends to the lower face of the photosensitive layer 10. For a large distance D2c, the lateral walls of the non-insolated region 12 have an even smaller slope, and meet to form a continuous curved wall in the photosensitive layer 10, without the depth of the non-insolated region 12 reaching the lower face of the photosensitive layer 10. The distance D2 thus allows to further control the inner dimensions of the non-insolated region 12, that is to say the dimensions transverse to the depth of the non-insolated region 12, in a plane parallel to the plane xy and below the plane comprising the exposed surface 10a.

The mass proportion of the scattering particles present in the photosensitive layer 10 also allows to control the inner dimensions of the non-insolated region 12 as well as the curvature of the curved walls. Indeed, the more the resin, here negative, is loaded with scattering particles, the more the radiation is scattered laterally in the photosensitive layer 10, which results in a low curvature of the wall. FIG. 4B illustrates three distinct mass proportions of scattering particles, Pa<Pb<Pc, for a fixed distance D2. As shown by FIG. 4B, the more the photosensitive layer is loaded with scattering particles, the greater the curvature of the curved wall.

FIG. 5A illustrates the geometry of the cavity 20 having curved lateral walls, obtained for a negative resin after the removal of the non-insolated region 12. An intersection of these walls with a plane substantially perpendicular to the plane xy forms curved lines. The radii of curvature of these curved lines extend at least partly in the cavity 20. Moreover, a transverse cross-section of the cavity 20 taken according to a plane in the photosensitive layer 10 parallel to the plane xy has a variable area according to the direction z. Preferably, this area decreases when moving away from the exposed surface 10a, and preferably over the entire height of the cavity 20. It should be noted that it is possible, for a portion of said curved lines, for these curved lines to have one or more radii of curvature that extend in the photosensitive layer 10.

For a first distance D2 and a first mass proportion of scattering particles, this cavity 20 has walls having a first slope, a first curvature and first inner dimensions. As described above, these parameters can be controlled, either by setting the first mass proportion of the scattering particles and by decreasing D2, as illustrated in FIG. 5B, or by setting the first distance D2 and by decreasing the mass proportion of the scattering particles, as illustrated in FIG. 5C. The geometry of the cavity 20 obtained for these two cases is illustrated in FIG. 5D. The geometry can thus be controlled according to the desired use. For an optoelectronic device 100, the geometry illustrated in FIG. 5A is more advantageous, as will be described below.

FIG. 6A illustrates the geometry of the stud 20′ having curved lateral walls, obtained for a positive resin after the removal of the insolated region 11. An intersection of these walls with a plane substantially perpendicular to the plane xy forms curved lines. The radii of curvature of these curved lines extend at least partly in the non-insolated region 12. It should be noted that it is possible, for a portion of said curved lines, for these curved lines to have one or more radii of curvature that extend in the space separating the studs 20′. Moreover, a transverse cross-section of the stud 20′ taken according to a plane in the photosensitive layer 10 parallel to the plane xy has a variable area according to the direction z. Preferably, this area decreases when moving away from the exposed surface 10a towards the substrate 10, and more preferably over the entire height of the stud 20′. The geometry of the stud 20′ illustrated in FIG. 6A, obtained for a first distance D2 and a first mass proportion of scattering particles, is not very stable and risks collapsing after the development. To improve the stability of this geometry, the same parameters, by analogy with FIGS. 5B and 5C, can be varied. FIG. 6B illustrates the more stable geometry of the studs 20′ obtained after the development, by varying these parameters.

According to a different example illustrated in FIG. 6C, occasional cavities can be obtained in a layer of positive resin with another configuration of mask 30, having an opaque region in which transparent regions 40, here in the form of openings, let the light radiation pass through. These cavities have an “overhanging” curved wall, which contrary to the cavity obtained in a negative resin, has a radius of curvature that does not extend inside the cavity but in the non-insolated region 12. This shape is not however optimal for the extraction of the light out of the cavity.

After the development step, the photosensitive layer 10 can advantageously undergo a second “strong” annealing heat treatment (“hard-bake”), which allows to improve the stability of the patterns 20, 20′. This second annealing heat treatment is implemented, preferably, at 180° C. for a duration of 10 min.

The defocused lithography method described above allows the manufacturing of a stack 1 comprising patterns 20, 20′ having curved walls that can correspond either to studs 20′ or to cavities 20. In the context of a use in optoelectronics, the stack 1 comprising cavities 20 manufactured in a photosensitive layer based on a negative resin can advantageously be integrated into an optoelectronic device 100. This optoelectronic device 100 comprises light-emitting diodes 50 (“LEDs”) emitting a light radiation at a first wavelength, preferably in the blue or in the UV. By configuring the cavities 20 having curved and reflective walls so that each cavity 20 at least partly exposes an active zone 50a of a distinct light-emitting diode 50, the performance of the optoelectronic device 100 can be improved, for example such as the extraction of the radiation emitted by the light-emitting diodes 50 and the improvement of the far-field emission of the radiation of the light-emitting diodes 50.

FIGS. 7, 8, 9A, 9B, 10, 11 and 12 schematically illustrate the various steps of manufacturing the optoelectronic device 100 according to the method described above.

As illustrated in FIG. 7, a multilayer assembly 1a comprises a substrate S surmounted by a plurality of light-emitting diodes 50. Each light-emitting diode 50 comprises a passive zone 50b surmounted by the active zone 50a. The substrate S can thus comprise an electric connection layer allowing the electric connection of the diodes 50. The substrate S can correspond to a backplane substrate for example, in which studs of electric connections and electric tracks are present previously and allow the control of the light-emitting diodes 50.

The multilayer assembly 1a can further comprise a preliminary layer 19 manufactured on the substrate S. The preliminary layer 19 is in particular configured so as to cover sides of the passive zone 50b and expose sides of the active zone 50a of each light-emitting diode 50. The preliminary layer 19 can be deposited on the substrate S by spin coating. It can be based a resin transparent to visible or white light. In order to stabilize the preliminary layer 19, a first soft heat treatment, for example at 110° C. for 2 min, can be implemented. This treatment can be followed by a step of insolation at an energy equal to 950 mJ. The insolation can be followed by a second strong heat treatment, for example at 180° C. for 10 min.

The photosensitive layer 10 comprising scattering particles having good reflectivity is then manufactured on the preliminary layer 19, according to the method described above. The photosensitive layer 10 preferably is based on a negative resin and covers upper faces and sides of the active zones 50a. It is possible for the optoelectronic device 100 to be manufactured with a positive resin, for example via the step of molding described above to form cavities. Hereinafter, the steps for a negative resin are described in more detail.

The improvement of the reflectivity of the photosensitive layer 10 allows to obtain cavities 20 having reflective curved walls. These walls being curved and reflective allow to improve the extraction of the light radiation emitted by the light-emitting diodes 50 by several reflections on the walls in the cavity 20 until their extraction. The arrangement of the diodes inside a cavity having walls and a bottom having a certain degree of reflectivity further allows to eliminate the need for a deposition of a metal layer acting as a mirror at the bottom of the cavity. This metal layer, based on aluminum for example, can lead to additional steps in the method for manufacturing the walls, like steps of deposition of the metal, of protection of the components such as the diodes by a mask, and the removal of the latter. Moreover, this metal layer, which is generally deposited on a substrate, of the backplane type for example, this substrate previously comprising light-emitting diodes, risks deteriorating the efficiency of the optoelectronic device.

As illustrated in FIG. 8, the insolated regions 11 and the non-insolated regions 12 are for example formed during the exposure of the photosensitive layer 10 to the incident light radiation 2 through the transparent regions 40 in the mask 30. The location of the transparent regions 40 is configured so as to form a non-insolated region 12 above each light-emitting diode 50. The parameters controlling the slope of the curved walls and the dimensions of the non-insolated regions 12, in particular the distance D2, are optimized in order for the curved walls of each non-insolated region 12 to be connected with a lower face of the active zone 50a of the corresponding light-emitting diode 50. This allows to improve the extraction of the light radiation emitted by the light-emitting diodes 50 inside the cavities 20.

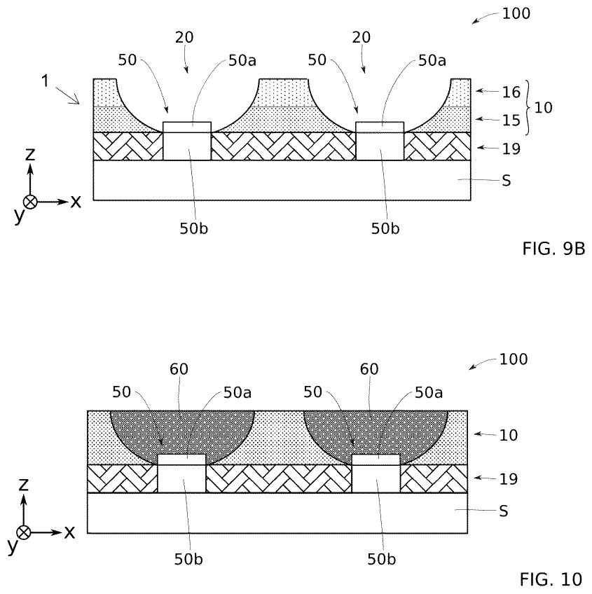

As illustrated in FIG. 9A, the non-insolated regions 12 can then be removed during a step of development, thus forming cavities 20, each cavity 20 exposing the upper face as well as the sides of the active zone 50a of the corresponding light-emitting diode 50.

In order to optimize the connection between the curved walls of the cavities 20 and the lower face of the active zone 50a, an overetching of the non-insolated regions 12 can be carried out. This overetching can remove up to 10 μm of thickness of the non-insolated region 12.

As illustrated in FIG. 9B, in order to modulate the slope of the curved walls of the cavities 20, according to an alternative of the present invention, the photosensitive layer 10 can comprise several sublayers 15, 16, as described above. Each sublayer 15, 16 can have a distinct mass proportion of scattering particles that increases between two successive sublayers when moving away from the exposed surface 10a.

As illustrated in FIG. 10, after the formation of the cavities 20, a solution 60 comprising color conversion modules is deposited in the cavities 20. The color conversion modules can be in the form of scattering photoluminescent blocks, comprising luminophores or particles of at least one photoluminescent material, dispersed for example in a transparent matrix (i.e. photosensitive resin). The photoluminescent particles can be in the form of quantum dots, that is to say in the form of semiconductor nanocrystals, the quantum confinement of which is substantially three-dimensional. The introduction of the color conversion modules into the cavities 20 allows the conversion of the first wavelength in the blue and/or UV of the radiation emitted by the light-emitting diode 50, by absorbing this radiation and by reemitting a light radiation at a different wavelength. According to one example, the first wavelength can be in the UV. In this case, this first wavelength can be reconverted into blue, by introducing color conversion modules configured to absorb the UV radiation and reemit a blue radiation. The wavelength of the light reemitted by the color conversion modules depends on the size and the composition of the photoluminescent particles present in the color conversion modules.

The parameters controlling the distance that separates two cavities 20 can be optimized in order to limit the optical crosstalk and improve the contrast between two juxtaposed light-emitting diodes 50. The optical crosstalk is the contamination of a wavelength emitted by the light-emitting diode or a wavelength remitted by the color conversion modules inside a cavity inside the neighboring cavity 20. The distance that separates two cavities 20 is preferably between 10um and 100um. The solution 60 comprising color conversion modules can further comprise scattering particles capable of scattering the radiation emitted by the light-emitting diodes 50 and the radiation reemitted by the color conversion modules, which improves on the one hand the conversion of the wavelength, and on the other hand, the extraction of the radiation reemitted by the color conversion modules.

Alternatively, the cavity 20 can be filled by a solution free of color conversion modules, comprising scattering particles. This allows to increase the scattering of the radiation emitted by the light-emitting diode 50, and consequently, to improve the extraction of this radiation. Certain cavities 20 can comprise a solution 60 comprising scattering particles and color conversion modules, and other cavities 20 can comprise a solution 60 comprising scattering particles and free of color conversion modules.

The solution 60 has a mass proportion of scattering particles smaller than the mass proportion of the scattering particles present in the photosensitive layer 10. Thus, the coupling between neighboring cavities is reduced. The extraction of the light radiation is further improved.

The depth of the cavity 20 can advantageously be optimized according to the concentration of the color conversion modules in the solution 60. The concentration of the color conversion modules in the solution 60, and in particular according to a thickness of the active zone 50a, influences the efficiency of the conversion of the wavelength. The depth of the cavity 20 can be adjusted according to the parameters of the method described above, and has a depth typically between 5 μm and 30 μm. Calculations show that beyond a threshold of 30 μm, the effect of the walls of the cavity 20 on the extraction of the light radiation emitted by the light-emitting diodes 50 becomes minimal, in particular in the case of an extraction of a blue radiation, because of the absorption of this radiation by the color conversion modules. Thus, the more the concentration of the color conversion modules in the solution 60 decreases, the more this threshold increases. Indeed, the efficiency of the walls is reduced according to its distance with the diodes 50. However, this distance depends on the concentration of color conversion modules in the solution 60. One reason for which the walls become less efficient is that the color conversion modules absorb the blue light of the light-emitting diode 50. Thus the lesser the concentration of the color conversion modules, the greater the threshold distance that makes the walls not very efficient. However, in the case of an extraction of a radiation at a wavelength greater than that of the blue, like that of the green or of the red for example, if the color conversion module is indeed configured to reemit a radiation at the correct wavelength, all the modules emit this wavelength. Consequently, the reflectivity of the wall significantly influences the extraction of the light, even if the cavities are deep enough.

The solution 60 comprising color conversion modules can fill the cavity 20 up to a height h60 (not illustrated) smaller or equal to the depth of the cavity 20. The height ho of the solution 60 is in particular configured so as to optimize the efficiency of conversion of the wavelength according to the concentration of color conversion modules as well as the mass proportion of scattering particles in the solution 60. The height heo of the solution 60 can be typically between 1 μm and 20 μm.

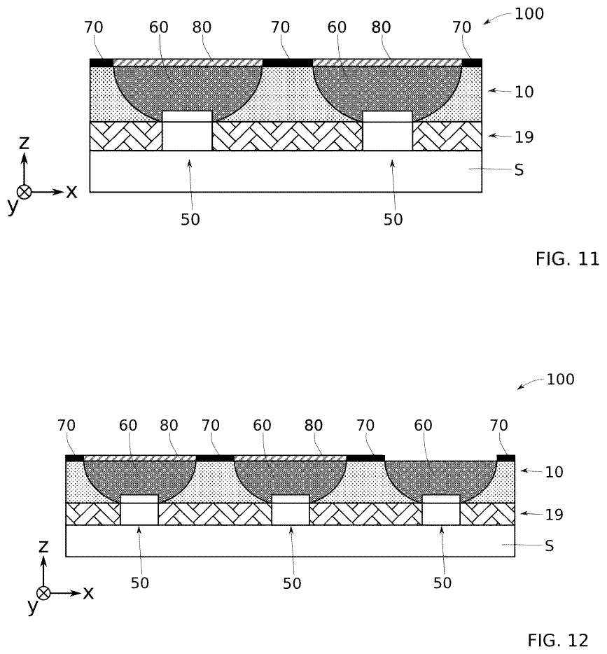

FIG. 11 illustrates two optional examples of the present invention. A first layer 70 opaque to the wavelengths of the visible can advantageously be manufactured on the exposed surface 10a of the photosensitive layer. This first opaque layer 70 allows in particular the improvement of the contrast between two light radiations emitted from two juxtaposed cavities 20. It covers for this at least partly, and preferably entirely, the exposed surface 10a of the photosensitive layer 10. The first opaque layer 70 can be configured so as to separate the cavities 20 from each other. The first layer 70 can be based on a resin. It can be deposited by spin coating using a mask having a configuration allowing the protection of the cavities 20 and the exposure of at least partly, and preferably entirely, the exposed surface 10a of the photosensitive layer 10. The first layer 70 typically has a thickness between 1 μm and 10 μm, preferably between 0.1 μm and 2 μm, according to the desired contrast.

As illustrated in FIG. 11, a second layer 80 opaque to the first wavelength in the blue of the light radiation emitted by the light-emitting diodes 50 can be manufactured. This second layer 80 can be configured to let the wavelengths reemitted by the color conversion modules pass through and block the first wavelength in the blue of the light radiation emitted by the light-emitting diodes 50. For this, the second layer 80 can be disposed above the cavities 20 comprising the solution 60 comprising color conversion modules. The second layer 80 has a thickness typically between 0.1 μm and 5 μm.

According to one example, the first layer 70 can be manufactured after the formation of the cavities 20 and before the introduction of the solution 60 into the cavities. The second layer 80 is then formed after the introduction of the solution 60 into the cavities. According to a more advantageous example, the second layer 80, then the first layer 70 are manufactured successively after the formation of the cavities 20 and the introduction of the solution 60 into the cavities. The manufacturing of the first layer 70 last allows in the context of a display device for example to improve the contrast and to obtain a clearer display. An additional non-illustrated barrier layer can be deposited on the solution 60 comprising color conversion modules. This barrier layer is used to protect the color conversion modules from the air and the ambient humidity.

This layer can be manufactured by atomic layer deposition (ALD). The barrier layer can be based on Al₂O₃.

FIG. 12 illustrates an alternative of the present invention, in which the optoelectronic device 100 comprises at least three distinct cavities 20 configured in the following manner:
A first light-emitting diode 50 emitting a light radiation at a first wavelength is disposed in a first cavity 20 comprising a first solution 60. The first solution 60 comprises first color conversion modules and scattering particles. The first color conversion modules are configured to convert the first wavelength, for example blue, into a second wavelength, preferably in the red. The second layer 80 is disposed above the first cavity 20 comprising the first solution 60, and lets the second wavelength pass through and blocks the first wavelength.
A second light-emitting diode 50 emitting a light radiation at a first wavelength is disposed in a second cavity 20 comprising a second solution 60. The second solution 60 comprises second color conversion modules and scattering particles. The second color conversion modules are configured to convert the first wavelength, for example blue, into a third wavelength distinct from the second wavelength, preferably in the green. The second layer 80 is disposed above the second cavity 20 comprising the first solution 60, and lets the third wavelength pass through and blocks the first wavelength.
A third light-emitting diode 50 emitting a light radiation at a first wavelength is disposed in a third cavity 20 comprising a third solution 60. The third solution 60 is preferably free of color conversion modules, and comprises scattering particles. The third cavity 20 is not covered by the second layer 80 in order to let the light radiation at the first wavelength emitted by the third light-emitting diode 50 pass through.

Preferably, the color conversion modules are quantum dots, that is to say in the form of semiconductor nanocrystals, the quantum confinement of which is substantially three-dimensional.

Such an optoelectronic device 100 can be used to form an emissive screen, wherein each cavity 20 comprising a light-emitting diode 50 and a solution 60 allowing the emission of a light radiation at a different wavelength forms a subpixel of this screen.

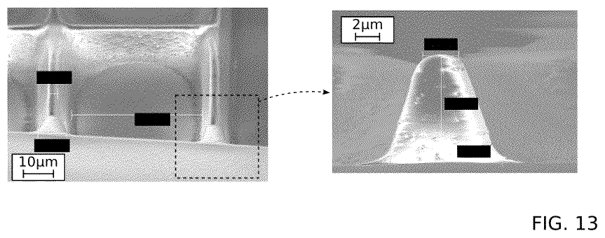

FIG. 13 shows images of the cavities having curved walls manufactured according to the present invention, taken by scanning electron microscopy. The image on the left shows as an example a transverse cross-section of a cavity. The image on the right shows a close-up view of a wall that separates two neighboring cavities, according to this example. These images clearly show that the method proposed offers a particularly efficient solution for forming patterns with curved walls, in particular cavities having curved walls.

The invention is not limited to the embodiments described above and extends to all the embodiments covered by the invention. Many other alternative embodiments are possible, for example by combination of features described above, without going beyond the context of the invention. Moreover, the features described relative to one aspect of the invention can be combined with another aspect of the invention.

1. A method for manufacturing by defocused lithography a stack comprising at least one pattern defined at least partly by a curved lateral wall so that an intersection of the curved wall with a plane substantially perpendicular to the plane of main extension of the stack forms a curved line, the method comprising:
providing a multilayer assembly comprising a substrate surmounted by a photosensitive layer, the photosensitive layer having an exposed surface and being based on a photosensitive resin comprising “scattering” particles, capable of scattering an incident light radiation,
providing a mask comprising at least one transparent region configured to transmit the incident light radiation,
placing the mask and the multilayer assembly so as to space them apart by a distance D1 configured so that the exposed surface of the photosensitive layer is not disposed in a focus plane of the incident light radiation,
the mask and the multilayer assembly being separated by the distance D1, an insolation of at least a part of the photosensitive layer by the incident light radiation transmitted through the at least one transparent region, wherein the incident light radiation is scattered laterally by the particles as the incident light radiation penetrates into the photosensitive layer, so as to form at least one insolated region defined at least partly by a curved lateral wall, and at least one non-insolated region,
forming the at least one pattern in the multilayer assembly, the formation comprising a removal of one out of the insolated region and the non-insolated region, to obtain the stack.

2. The method according to claim 1, wherein the distance D1 is strictly greater than a distance between the mask and the focus plane, said distance D1 being chosen so that the exposed surface is distant from the focus plane by a distance D2 of between 100 nm and 100 μm.

3. The method according to claim 1, wherein the scattering particles are chosen from the group consisting of: oxides of metals having the formula MₓO_{y}, with x, y non-zero positive integers, and nanoparticles based on at least one metal.

4. The method according to claim 1, wherein the photosensitive layer is based on a negative photosensitive resin, so that, during the formation of the at least one pattern, the removal of the non-insolated region induces the formation of at least one cavity defined at least partly by said curved lateral wall.

5. The method according to claim 1, wherein the photosensitive resin has a mass proportion of scattering particles between 1% and 40%.

6. The method according to claim 1, wherein the scattering particles have a reflectivity between 20% and 100%.

7. The method according to claim 1, wherein the photosensitive layer comprises several sublayers at least partly superimposed, each sublayer having a mass proportion of scattering particles distinct among the several sublayers, the mass proportion increasing between two superimposed sublayers when moving away from the exposed surface.

8. The method according to claim 1, wherein the at least one insolated region is subjected to an insolation dose of between 50 mJ/cm² and 3000 mJ/cm².

9. The method according to claim 1, wherein the photosensitive layer is based on a negative photosensitive resin, so that, during the formation of the at least one pattern, the removal of the non-insolated region induces the formation of at least one cavity defined at least partly by said curved lateral wall, and there is at least one light-emitting diode above the substrate of the stack disposed at the interface between the substrate and the photosensitive layer, and the insolation is configured so that the cavity at least partly exposes the at least one light-emitting diode.

10. The method according to claim 9, comprising, after the formation of the at least one cavity, the deposition of a solution comprising color conversion modules in the at least one cavity exposing the at least one light-emitting diode, the at least one light-emitting diode being configured to emit a light radiation having a first wavelength, the color conversion modules being configured to convert the first wavelength into a second wavelength distinct from the first wavelength.

11. The method according to claim 10, wherein the solution comprising color conversion modules further comprises scattering particles capable of scattering a radiation emitted by the at least one light-emitting diode, said solution having a mass proportion of scattering particles smaller than a mass proportion of the scattering particles in the photosensitive layer.

12. A stack comprising:
a substrate surmounted by a photosensitive layer based on a photosensitive resin comprising particles capable of scattering an incident light radiation having a first mass percentage,
the photosensitive layer comprising at least one pattern at least partly defined by a curved lateral wall so that an intersection of the curved lateral wall with a plane substantially perpendicular to the plane of main extension of the stack forms a curved line, the photosensitive layer having an exposed surface, and the at least one pattern opening onto the exposed surface, the at least one pattern having, in the plane of main extension of the stack, a transverse cross-section increasing along a direction perpendicular to the plane of main extension of the stack when moving away from the substrate.

13. The stack according to claim 12, wherein the at least one pattern has a depth of between 5 μm and 30 μm.

14. The stack according to claim 12, wherein the at least one pattern is at least one cavity at least partly defined by said curved lateral wall.

15. An optoelectronic device comprising the stack according to claim 12, and at least one light-emitting diode, wherein the pattern surmounts the light-emitting diode.

16. The optoelectronic device according to claim 15, wherein the at least one pattern is at least one cavity defined at least partly by said curved lateral wall, and the at least one light-emitting diode is disposed in the at least one cavity, said cavity being configured so as to at least partly expose the light-emitting diode.

17. The optoelectronic device according to claim 16, comprising a solution in the at least one cavity, the solution comprising color conversion modules and scattering particles, said solution having a mass proportion of scattering particles smaller than a mass proportion of the scattering particles in the photosensitive layer, the at least one light-emitting diode being configured to emit a light radiation having a first wavelength, the color conversion modules being configured to convert the first wavelength into a second wavelength distinct from the first wavelength.

18. The optoelectronic device according to claim 17, comprising at least three light-emitting diodes configured to emit a light radiation having a first wavelength, and disposed so that:
a first light-emitting diode is disposed in a first cavity comprising a first solution, the first solution comprising first color conversion modules and scattering particles, the first color conversion modules being configured to convert the first wavelength of the light radiation emitted by the first light-emitting diode into a second wavelength different from the first wavelength,
a second light-emitting diode is disposed in a second cavity comprising a second solution, the second solution comprising second color conversion modules and scattering particles, the second color conversion modules being configured to convert the first wavelength of the light radiation emitted by the second light-emitting diode into a third wavelength different from the first and second wavelengths,
a third light-emitting diode is disposed in a third cavity comprising a third solution, the third solution comprising scattering particles.
